(19) United States
(12) Patent Application Publication
(10) Pub. No.: US 2008/0179676 A1
(43) Pub. Date: Jul. 31, 2008

(54) SEMICONDUCTOR MEMORY DEVICE

(76) Inventors: Yuichi HIRANO, Tokyo (JP); Takashi Ipposhi, Tokyo (JP); Toshiaki Iwamatsu, Tokyo (JP); Yukio Maki, Tokyo (JP); Mikio Tsujiuchi, Tokyo (JP)

Correspondence Address: MILES & STOCKBRIDGE PC, 1751 PINNACLE DRIVE, SUITE 500, MCLEAN, VA, 22102-3833, US

(21) Appl. No.: 11/971,434

(22) Filed: Jan. 9, 2008

(30) Foreign Application Priority Data
Jan. 30, 2007 (JP) 2007-019185

(51) Int. Cl. H01L 27/12

(52) U.S. Cl. 257/350; 257/E27.112

(57) ABSTRACT

While reducing the formation area of a SRAM cell, the variation in electrical characteristics of respective transistors is suppressed. In a SRAM cell formed in a SOI board, the electrical coupling between the drain region of a driver transistor (which is also a source/drain region of an access transistor), and the drain region of a load transistor, and the electrical coupling between the drain region of another driver transistor (which is also a source/drain region of another access transistor) and the drain region of another load transistor are established by wiring structures formed by using a SOI layer under an isolation oxide film which is partial trench isolation, respectively.

### CROSS-REFERENCE TO RELATED APPLICATIONS

The disclosure of Japanese Patent Application No. 2007-19185 filed on Jan. 30, 2007 including the specification, drawings and abstract is incorporated herein by reference in its entirety.

### BACKGROUND OF THE INVENTION

The present invention relates to a semiconductor memory device. More particularly, it relates to a wiring structure of a SRAM (Static Random Access Memory) formed by using a SOI (Silicon On Insulator) board.

As a device capable of improving the performances of a semiconductor device, there is widely known a SOI device using a SOI board including a lamination of a support board, a buried oxide film (BOX layer), and a silicon layer (SOI layer). For example, a MOS (Metal-Oxide Semiconductor) transistor formed in a SOI board is small in parasitic capacitance of the source/drain region, and is capable of high-speed and low power consumption operation.

In the SOI device, as the trench isolation for isolating between elements such as transistors, there are FTI: Full Trench Isolation for completely separating the SOI layer, or PTI: Partial Trench Isolation formed only at the upper part of the SOI layer. Below, the full trench isolation and the partial trench isolation are referred to as “full isolation” and “partial isolation”, respectively.

In general, the electrical potential of the body which is a region where a channel of a transistor is formed is fixed at a given value for stabilizing the operation of the transistor. However, with the device structure having partial isolation, a specific electrical potential can be applied to the body through the SOI layer under the partial isolation. Accordingly, a control terminal of the body electrical potential is not required to be disposed in the same active region as that for the transistor. This can contribute to the reduction of the parasitic capacitance of the transistor. Further, by electrically coupling the bodies of a plurality of the same conductivity type of transistors through the SOI layer under the partial isolation, it is possible to collectively control the body electrical potentials of the transistors by one control terminal. This can also contribute to the reduction of the formation area.

Further, there is also proposed a semiconductor device structure in which the drain region of a P channel type MOS (PMOS) transistor and the drain region of an N channel type MOS (NMOS) transistor are coupled through the SOI layer under partial isolation (e.g., Patent Documents 1 to 3).

[Patent Document 1]

Japanese Patent Laid-Open No. 2001-352042

[Patent Document 2]

Japanese Patent Laid-Open No. 2002-9299

[Patent Document 3]

Japanese Patent Laid-Open No. 2001-274265

### SUMMARY OF THE INVENTION

As one of devices using transistors formed in a SOI board, mention may be made of a SRAM. A general SRAM memory cell (SRAM cell) has an NMOS transistor for data transmission (access transistor), and a flip-flop circuit holding the data. The flip-flop circuit includes two inverters coupled to each other. Each inverter includes an NMOS transistor for driving (driver transistor), and a PMOS transistor for load (load transistor).

The access transistor and the driver transistor are of the same conductivity type (in this example, N channel type). Therefore, by forming both in the same active region, it is possible to establish an electrical coupling between both. On the other hand, a driver transistor and a load transistor forming an inverter are of mutually different conductivity types. Therefore, in the related art, they are formed in different active regions, and the electrical coupling between both is established through wiring formed on an interlayer insulation film covering the SRAM cell.

Whereas, in recent years, there is also the following technique. The active regions are laid out so that the drain region of a driver transistor and the drain region of a load transistor are coupled to each other. Thus, an integral silicide layer is formed on the drain regions of the two, so that the electrical coupling therebetween is established through the silicide layer. With a SRAM cell having the active regions thus laid out, it is known that the cell area and the bit line capacitance can be reduced by about 11% and about 26%, respectively, as compared with a conventional one.

However, in the SRAM cell using the layout of the active regions, a variation in electrical characteristics of respective transistors becomes a problem. The reason for this is as follows. The actually formed active region has rounded corner portions. Therefore, when the drain region of the driver transistor and the drain region of the load transistor are formed in a coupled form, the active region increases in width in the vicinity of the coupling portion (see, FIG. 4). Accordingly, when deviation is generated in alignment of the gate electrodes, the gate width of each transistor largely changes (the details of which will be described later). When a variation in electrical characteristics of respective transistors increases, the operation margin of the SRAM decreases, unfavorably resulting in reductions of the operation reliability and the manufacturing yield.

The present invention was completed in order to solve the foregoing problem. It is therefore an object of the invention to suppress the variation in electrical characteristics of respective transistors while reducing the formation area of a SRAM cell.

A semiconductor memory device in accordance with the present invention includes a SRAM cell including a SOI board including a support board, an insulation film, and a semiconductor layer stacked in this order, first and second active regions defined by trench isolation in the semiconductor layer, an access transistor and a driver transistor which are MOS transistors formed in the first active region, and a load transistor which is a MOS transistor formed in the second active region, wherein the electrical coupling between a drain region of the driver transistor and a drain region of the load transistor is established by a wiring structure formed by using the semiconductor layer present under the trench isolation.

In accordance with the present invention, a first active region and a second active region are not required to be coupled at the upper part of a SOI layer. This prevents the roundness of the corner portion occurring upon forming the active regions from widening the width of the first and second active regions. Therefore, even when misalignment of gate electrodes of respective transistors occurs, the gate width of each of the transistors shows almost no changes. This can suppress the variation in electrical characteristics thereof. Still further, as compared with the case using the wiring of the overlying layer, the cell area and the bit line capacitance can be reduced. The SOI layer under trench isolation is relatively high in resistance, which functions as a feedback resistance. This provides an effect of reducing a soft error.

### BRIEF DESCRIPTION OF THE DRAWINGS

FIG. 1 is a circuit diagram of a general SRAM cell;

FIG. 2 is a top view of a layout of a conventional SRAM cell;

FIG. 3 is a view showing the mutual coupling structure of an access transistor, a driver transistor, and a load transistor in the conventional SRAM cell;

FIG. 4 is an enlarged top view of the vicinity of the drain region of the driver transistor of the conventional SRAM cell;

FIG. 5 is a top view showing a layout of a SRAM cell in accordance with Embodiment 1;

FIG. 6 is a view showing the mutual coupling structure of an access transistor, a driver transistor, and a load transistor in the SRAM cell in accordance with Embodiment 1;

FIG. 7 is an enlarged top view of the vicinity of a drain region of a driver transistor of the SRAM cell in accordance with Embodiment 1;

FIG. 8 is a view showing a manufacturing step of the SRAM cell in accordance with Embodiment 1;

FIG. 9 is a view showing a manufacturing step of the SRAM cell in accordance with Embodiment 1;

FIG. 10 is a view showing a manufacturing step of the SRAM cell in accordance with Embodiment 1;

FIG. 11 is a view showing a manufacturing step of the SRAM cell in accordance with Embodiment 1;

FIG. 12 is a view showing a manufacturing step of the SRAM cell in accordance with Embodiment 1;

FIG. 13 is a view showing a manufacturing step of the SRAM cell in accordance with Embodiment 1;

FIG. 14 is a view showing a manufacturing step of the SRAM cell in accordance with Embodiment 1;

FIG. 15 is a view showing a manufacturing step of the SRAM cell in accordance with Embodiment 1;

FIG. 16 is a view showing a manufacturing step of the SRAM cell in accordance with Embodiment 1;

FIG. 17 is a view showing a manufacturing step of the SRAM cell in accordance with Embodiment 1;

FIG. 18 is a view showing a manufacturing step of the SRAM cell in accordance with Embodiment 1;

FIG. 19 is a view showing a manufacturing step of the SRAM cell in accordance with Embodiment 1;

FIG. 20 is a view showing the mutual coupling structure of an access transistor, a driver transistor, and a load transistor in a SRAM cell in accordance with Embodiment 2;

FIG. 21 is a view showing a manufacturing step of the SRAM cell in accordance with Embodiment 2;

FIG. 22 is a view showing a manufacturing step of the SRAM cell in accordance with Embodiment 2;

FIG. 23 is a view showing a manufacturing step of the SRAM cell in accordance with Embodiment 2;

FIG. 24 is a view showing a manufacturing step of the SRAM cell in accordance with Embodiment 2;

FIG. 25 is a view showing the mutual coupling structure of an access transistor, a driver transistor, and a load transistor in a SRAM cell in accordance with Embodiment 3;

FIG. 26 is a view showing a manufacturing step of the SRAM cell in accordance with Embodiment 3;

FIG. 27 is a view showing a manufacturing step of the SRAM cell in accordance with Embodiment 3;

FIG. 28 is a view showing a manufacturing step of the SRAM cell in accordance with Embodiment 3;

FIG. 29 is a view showing a manufacturing step of the SRAM cell in accordance with Embodiment 3;

FIG. 30 is a view showing the mutual coupling structure of an access transistor, a driver transistor, and a load transistor in a SRAM cell in accordance with Embodiment 4;

FIG. 31 is a view showing a manufacturing step of the SRAM cell in accordance with Embodiment 4;

FIG. 32 is a view showing a manufacturing step of the SRAM cell in accordance with Embodiment 4;

FIG. 33 is a view showing a manufacturing step of the SRAM cell in accordance with Embodiment 4;

FIG. 34 is a view showing a manufacturing step of the SRAM cell in accordance with Embodiment 4;

FIG. 35 is a top view showing a layout of a SRAM cell in accordance with Embodiment 5;

FIG. 36 is a view showing the mutual coupling structure of an access transistor, a driver transistor, and a load transistor in a SRAM cell in accordance with Embodiment 5;

FIG. 37 is a view showing a manufacturing step of the SRAM cell in accordance with Embodiment 5;

FIG. 38 is a view showing a manufacturing step of the SRAM cell in accordance with Embodiment 5;

FIG. 39 is a top view showing a layout of a SRAM cell in accordance with Embodiment 6;

FIG. 40 is a view showing the mutual coupling structure of an access transistor, a driver transistor, and a load transistor in the SRAM cell in accordance with Embodiment 6;

FIG. 41 is a view showing a manufacturing step of the SRAM cell in accordance with Embodiment 6;

FIG. 42 is a view showing a manufacturing step of the SRAM cell in accordance with Embodiment 6;

FIG. 43 is a top view of a layout of a SRAM cell in accordance with Embodiment 7;

FIG. 44 is a view showing the mutual coupling structure of an access transistor, a driver transistor, and a load transistor in the SRAM cell in accordance with Embodiment 7; and

FIG. 45 is a top view showing a layout of a SRAM cell in accordance with Embodiment 8.

### DETAILED DESCRIPTION OF THE PREFERRED EMBODIMENTS

### Embodiment 1

First, prior to the description of the present invention, a constitution of a conventional general SRAM cell will be described.

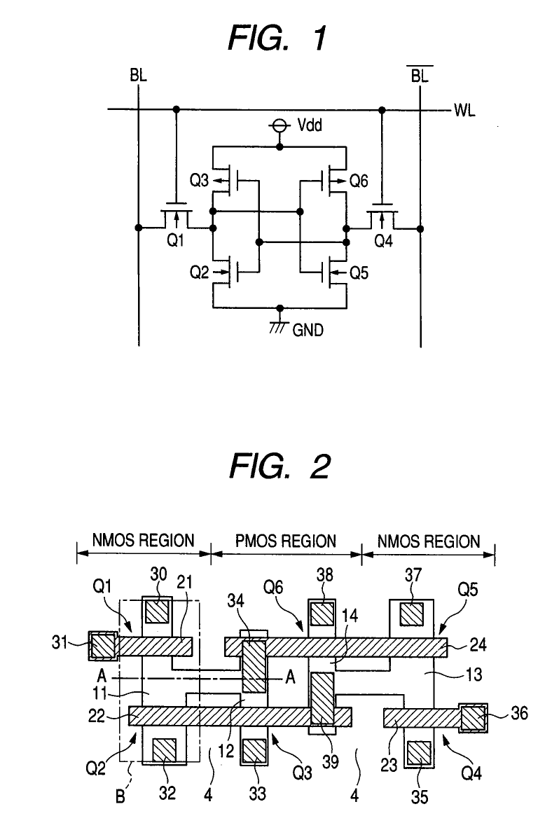

FIG. 1 is a circuit diagram of a memory cell (SRAM cell) of a general SRAM. As shown in the same diagram, the SRAM cell has access transistors Q1 and Q4 which are NMOS transistors for data transmission, and a flip-flop circuit for storing the data. The flip-flop circuit includes an inverter including a driver transistor Q2 which is an NMOS transistor for driving and a load transistor Q3 which is a PMOS transistor for load, and an inverter similarly including a driver transistor Q5 and a load transistor Q6, mutually coupled. Thus, to a word line WL, the gates of the access transistors Q1 and Q4 are coupled, and to bit lines BL and /BL, the source/drain of the access transistors Q1 and Q4 are coupled, respectively.

FIG. 2 is a top view showing the layout of a conventional SRAM cell. In the same view, the elements corresponding to those shown in FIG. 1 are given the same reference numerals and signs. The SRAM cell is formed on a SOI board. Further, in the description below, as shown in FIG. 2, the formation region of the access transistors Q1 and Q4 and the driver transistors Q2 and Q5 which are NMOS transistors is referred to as an “NMOS region”, and the formation region of the load transistors Q3 and Q6 is referred as a “PMOS region”.

With the layout of FIG. 2, the NMOS region of the access transistor Q1 and the driver transistor Q2, and the NMOS region of the access transistor Q4 and the driver transistor Q5 are disposed in such a manner as to interpose the PMOS region of the load transistors Q3 and Q6 therebetween. In the NMOS regions and the PMOS region, active regions 11 to 14 defined by an isolation oxide film 4 serving as trench isolation are formed. Respective transistors Q1 to Q6 are formed therein.

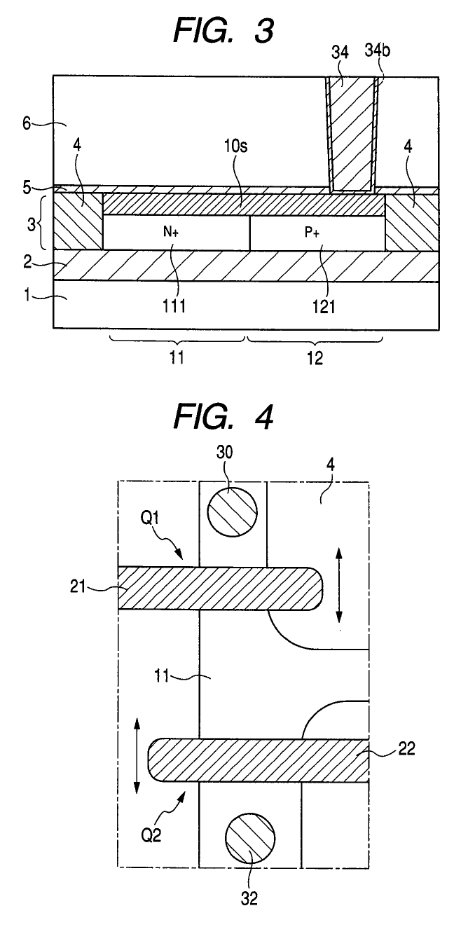

More specifically, in the NMOS region on the left side of the PMOS region, the first active region 11 is formed. In the first active region 11, the access transistor Q1 and the driver transistor Q2 are formed. Whereas, in the NMOS region on the right side of the PMOS region, the third active region 13 is formed. In the third active region 13, the access transistor Q4 and the driver transistor Q5 are formed. In the PMOS region, the second and fourth active regions 12 and 14 are formed. In the second active region 12, the load transistor Q3 is formed, and in the fourth active region 14, the load transistor Q6 is formed. As indicated from FIG. 2, the group of the access transistor Q1, the driver transistor Q2, and the load transistor Q3, and the group of the access transistor Q4, the driver transistor Q5, and the load transistor Q6 are disposed symmetrically with respect to each other.

Whereas, in the example of FIG. 2, the first active region 11 and the second active region 12 are formed integrally so that the drain region of the driver transistor Q2 and the drain region of the load transistor Q3 are coupled to each other. Similarly, the third active region 13 and the fourth active region 14 are formed integrally so that the drain region of the driver transistor Q5 and the drain region of the load transistor Q6 are coupled to each other. Although not shown in FIG. 2, on the top side of the active regions 11 to 14, a silicide layer is formed. The electrical couplings between the drain region of the driver transistor Q2 and the drain region of the load transistor Q3, and between the drain region of the driver transistor Q5 and the drain region of the load transistor Q6 are established through the silicide layer (see, FIG. 3).

On the active regions 11 to 14, gate electrodes 21 to 24 each extending in the lateral direction (corresponding to the direction of extension of a word line WL) are formed. Namely, the gate electrode 21 crosses over the first active region 11, functions as a gate of the access transistor Q1, and is coupled to the overlying word line WL (not shown) through a contact 31. The gate electrode 22 crosses over the first active region 11, the second active region 12, and the fourth active region 14, and functions as a gate of both the driver transistor Q2 and the load transistor Q3. In addition, the gate electrode 22 is coupled to the drain region of the load transistor Q6 through a contact 39 (shared contact).

Whereas, the gate electrode 23 crosses over the third active region 13, and functions as the gate of the access transistor Q4. In addition, it is coupled to the overlying word line WL through a contact 36. The gate electrode 24 crosses over the second active region 12, the third active region 13, and the fourth active region 14, and functions as a gate of the driver transistor Q5 and the load transistor Q6. In addition, it is coupled to the drain region of the load transistor Q3 through a contact 34 (shared contact).

Whereas, the contact 30 is for coupling the source/drain of the access transistor Q1 and the overlying bit line BL (not shown). The contact 35 is for coupling the source/drain of the access transistor Q4 and the overlying bit line /BL (not shown). Still further, the contacts 32 and 37 are for coupling the source of the driver transistors Q2 and Q5 to the overlying ground (GND) line (not shown), respectively. The contacts 33 and 38 are for coupling the source of the transistors Q3 and Q6 to the overlying power supply (Vdd) wiring (not shown).

In accordance with the layout shown in FIG. 2, respective active regions 11 to 14, and respective gate electrodes 22 to 24 are each in a simple form. Accordingly, the layout is suitable for the reduction of the SRAM cell formation area.

FIG. 3 is a view showing the mutual coupling structure of the access transistor Q1, the driver transistor Q2, and the load transistor Q3 in the SRAM cell of FIG. 2, and is a cross sectional view along line A-A of FIG. 2. In other words, the same view shows the cross sections of the drain region of the driver transistor Q2 (which is also the source/drain region of the access transistor Q1), and the drain region of the load transistor Q3. Incidentally, the access transistor Q4, the driver transistor Q5, and the load transistor Q6 are similar in configuration to the access transistor Q1, the driver transistor Q2, and the load transistor Q3, respectively. Therefore, herein, a description will be typically given to the coupling structure among the access transistor Q1, the driver transistor Q2, and the load transistor Q3.

As in FIG. 3, the SRAM cell is formed on a SOI board including a support board 1, a BOX layer 2, and a SOI layer 3 stacked one on another in this order. In the SOI layer, an isolation oxide film 4 as a trench isolation is formed. The first active region 11 and the second active region 12 are defined by the isolation oxide film 4. In the cross section shown in FIG. 3, in the first active region 11, an N⁺ region 111 (which is hereinafter referred to as a “drain region 111”) which is the drain region of the driver transistor Q2 is formed. In the second active region 12, a P⁺ region 121 (which is hereinafter referred to as a “drain region 121”) which is the drain region of the load transistor Q3 is formed. The top of the SRAM cell is covered with a silicon nitride film 5 and an interlayer insulation film 6, in which a shared contact 34 to be coupled to the drain region 121 is formed. Although omitted in FIG. 2, the shared contact 34 has a barrier metal 34b on the surface.

As described previously, in the SRAM cell of FIG. 2, on the top surface of the drain region 111 of the driver transistor Q2 and the drain region 121 of the load transistor Q3, a silicide layer 10s is integrally formed. This establishes an electrical coupling between the drain region 111 of the driver transistor Q2 and the drain region 121 of the load transistor Q3. Further, the following is known. With this configuration, as compared with the case where the drain region 111 of the driver transistor Q2 and the drain region 121 of the load transistor Q3 are coupled to each other by the use of the overlying wiring, the cell area can be reduced by about 11%, and the bit line capacitance can be reduced by about 26%.

However, in the SRAM cell of this layout, a variation in electrical characteristics of the transistors Q1 to Q6 becomes a problem. FIG. 4 is a view for illustrating the reason, and an enlarged view of a region B shown in FIG. 2. The actually formed active region has rounded corner portions. Therefore, when a part of the first active region 11 is extended in the direction of the second active region 12 as in FIG. 4, the width of the first active region 11 increases in the vicinity of the portion. In that case, when misalignment between the gate electrodes 21 and 22 occurs in the direction of gate length (in the direction of a bidirectional arrow of FIG. 4), each gate length of the driver transistor Q1 and the driver transistor Q2 largely changes, which causes a variation in electrical characteristics. The same also applies to the transistors Q3 to Q6 not shown in FIG. 4. When the variation in electrical characteristics increases, the operation margin of the SRAM decreases. This unfavorably results in reductions of operation reliability and manufacturing yield.

Below, a description will be given to a SRAM cell in accordance with the invention capable of solving this problem.

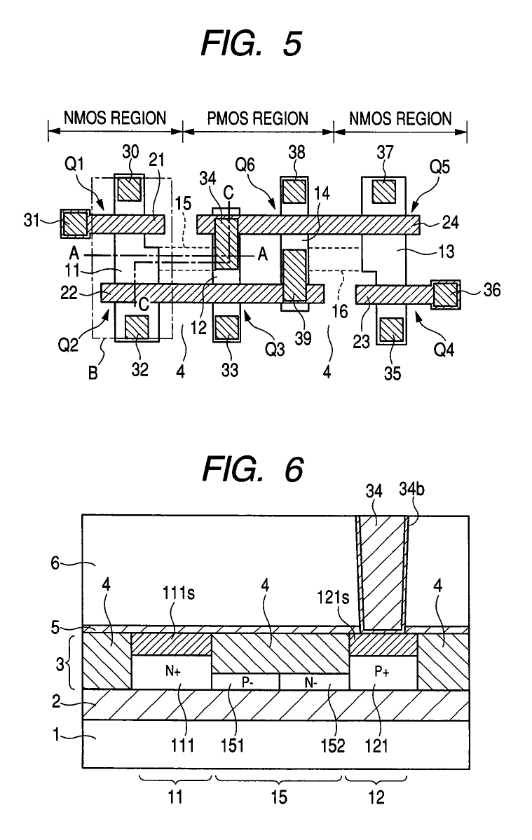

FIG. 5 is a top view showing a layout of a SRAM cell in accordance with Embodiment 1 of the invention. Further, FIG. 6 is a cross sectional view along line A-A thereof, and shows the coupling structure between the driver transistor Q2 and the load transistor Q3. Incidentally, in FIGS. 5 and 6, the elements having the same functions as those shown in FIGS. 2 and 3 are given the same reference numerals and signs. Therefore, a description thereon is omitted.

Whereas, also in this embodiment, the group of the access transistor Q1, the driver transistor Q2, and the load transistor Q3, and the group of the access transistor Q4, the driver transistor Q5, and the load transistor Q6 are disposed symmetrically with respect to each other, and have the mutually same configuration. Thus, also herein, the coupling structure between the access transistor Q1, the driver transistor Q2, and the load transistor Q3 will be typically described.

In the SRAM cell in accordance with Embodiment 1, distinct from the case of FIG. 2 or FIG. 3, the first active region 11 and the second active region 12 are not coupled through the upper part of the SOI layer 3. They are isolated therebetween by the isolation oxide film 4. However, as shown in FIG. 6, the isolation oxide film 4 between the drain region 111 of the driver transistor Q2 (which is also the source/drain region of the access transistor Q1) and the drain region 121 of the load transistor Q3 does not extend to the BOX layer 2. Under the isolation oxide film 4, the lower layer portion of the SOI layer 3 remains. In other words, the isolation oxide film 4 of the region is partial trench isolation (PTI). The drain region 111 of the driver transistor Q2 and the drain region 121 of the load transistor Q3 are coupled via the SOI layer 3 under the isolation oxide film 4.

In the SRAM cell of the invention, as a wire for electrically coupling the drain region 111 of the driver transistor Q2 and the drain region 121 of the load transistor Q3, there is used the SOI layer 3 present under the isolation oxide film 4 therebetween. Below, the SOI layer 3 under the isolation oxide film 4 functioning as the wire is referred to as a “wire structure”. As shown in FIG. 5, a wiring structure 15 is disposed between the drain region of the driver transistor Q2 and the drain region of the load transistor Q3. Whereas, a wiring structure 16 is also disposed between the drain region of the driver transistor Q5 and the drain region of the load transistor Q6 (herein, typically, the wiring structure 15 will be described).

As shown in FIG. 6, in this embodiment, in the wiring structure 15 between an N⁺ type drain region 111 and a P⁺ type drain region 121, a P⁻ region 151 is formed on the drain region 111 side. An N⁻ region 152 is formed on the drain region 121 side. Therefore, in the wiring structure 15, PN junctions are formed at three sites of the boundary between the drain region 111 and the P⁻ region 151, the boundary between the P⁻ region 151 and the N⁻ region 152, and the boundary between the N⁻ region 152 and the drain region 121. As a result, the wiring structure 15 does not conduct electricity as it is, and it cannot be allowed to function as a wire.

Thus, in this embodiment, to the wiring structure 15, ion implantation of, for example, Si, N, F, Ge, As, P, BF₂, B, In, or Ar is performed to cause a crystal defect. Then, the leak current caused thereby is generated at the PN junction. In other words, the leak current establishes an electrical coupling between the drain region 111 of the driver transistor Q2 and the drain region 121 of the load transistor Q3. The magnitude of the leak current can be set at about 10⁻⁹ A to 1 A.

Alternatively, the following may be adopted. After the step of forming the silicide layer of CoSi, NiSi, or the like in the upper parts of the active regions 11 to 14 and the gate electrodes 21 to 24, ions of Si or the like are implanted. As a result, metal atoms of Co or Ni used in the silicidation are knocked on to be introduced into the wiring structure 15. This causes a leak current at the PN junction.

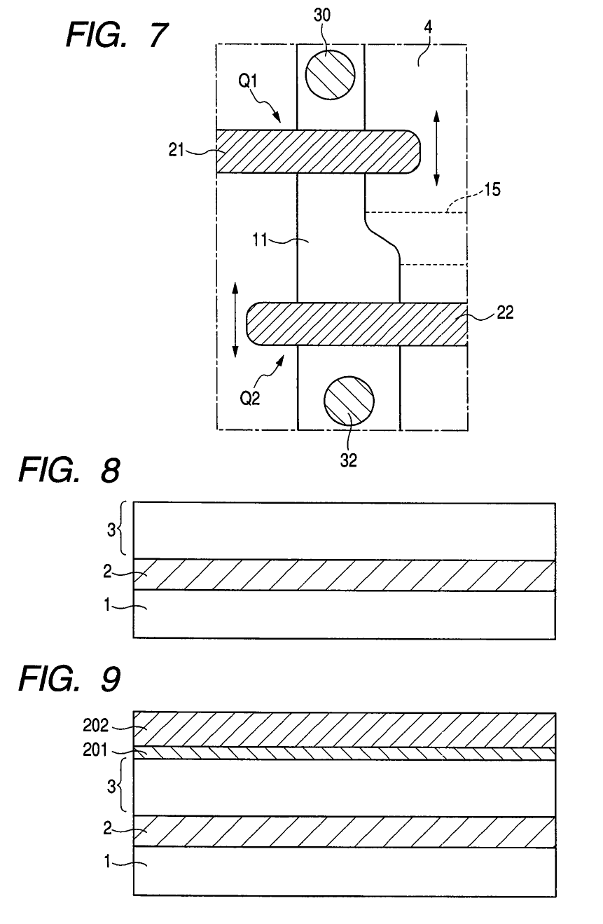

FIG. 7 is an enlarged top view of the vicinity of the drain region of the driver transistor Q2 of the SRAM cell in accordance with Embodiment 1, and an enlarged view of the region B of FIG. 5. With the layout of The SRAM cell in accordance with Embodiment 1, the first active region 11 and the second active region 12 are not coupled with each other through the upper part of the SOI layer 3. They are isolated therebetween by the isolation oxide film 4. Accordingly, as shown in FIG. 7, there will not occur widening of the width of the first active region 11 by the roundness of the corner portions generated upon forming the active regions. This is apparent from comparison with the conventional example shown in FIG. 4.

Therefore, in accordance with this embodiment, even when misalignment between the gate electrodes 21 and 22 occurs in the direction of the gate length (in the direction of a bidirectional arrow of FIG. 7), each gate width of the driver transistor Q1 and the driver transistor Q2 shows almost no changes. This can suppress the variation in electrical characteristics thereof (the same effects can be obtained even for the transistors Q3 to Q6 not shown in FIG. 7). Furthermore, as with the SRAM cell shown in FIGS. 2 and 3, as compared with the case where the drain region 111 of the driver transistor Q2 and the drain region 121 of the load transistor Q3 are coupled to each other by the use of the overlying wiring, the cell area and the bit line capacitance can be reduced. Whereas, the coupling between the drain region 111 of the driver transistor Q2 and the drain region 121 of the load transistor Q3 is established by the relatively high resistance wiring structure 15. As a result, that functions as a feedback resistance, which also produces an effect of reducing a soft error.

Below, a description will be given to the manufacturing process of the SRAM cell in accordance with Embodiment 1. FIGS. 8 to 19 are views showing the manufacturing process of the SRAM cell in accordance with Embodiment 1. These respective views each correspond to the cross section along line C-C of FIG. 5.

First, there is prepared a SOI board including a BOX layer 2 with a thickness of about 50 to 200 nm, and a SOI layer 3 with a thickness of about 50 to 150 nm stacked on a support board 1 (FIG. 8). Then, thereon, a silicon oxide film 201 with a thickness of several tens of nanometers is formed. Further, a silicon nitride film 202 with a thickness of about several hundreds of nanometers is formed (FIG. 9).

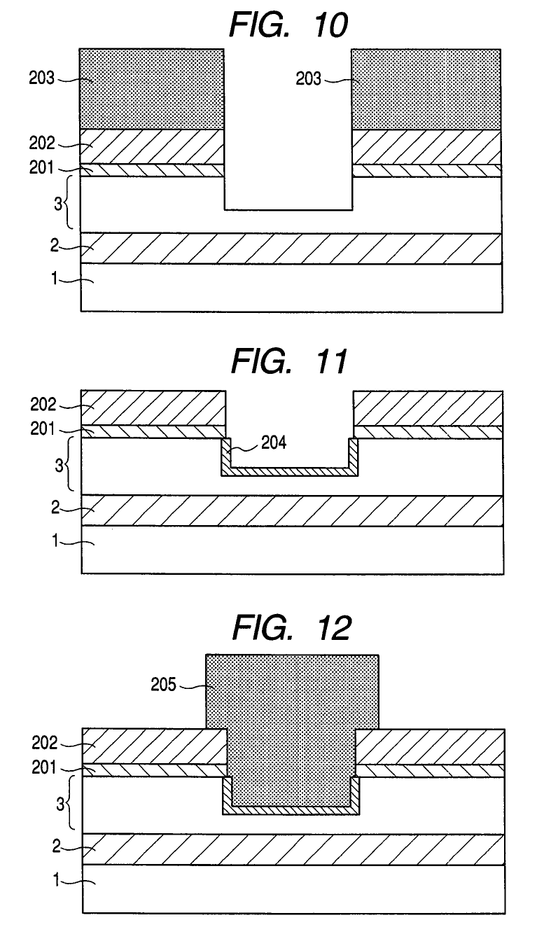

Subsequently, a resist 203 is formed on the region in which the active regions 11 to 14 are formed. Then, by etching using the resist 203 as a mask, the silicon nitride film 202, the silicon oxide film 201, and the SOI layer 3 are patterned to form a trench for the isolation oxide film 4. The etching at this step is stopped with the bottom portion of the SOI layer 3 left (FIG. 10).

After removing the resist 203, a sidewall oxide film 204 is formed to about 10 nm on the inner wall of the exposed trench (FIG. 11). Then, a resist 205 is formed in such a manner as to cover the region to serve as partial trench isolation including the formation region of the wiring structures 15 and 16 (FIG. 12). Then, with etching by the use of the silicon nitride film 202 and the resist 205 as a mask, the SOI layer 3 is further dug down to form a trench (not shown) for full isolation extending to the BOX layer 2.

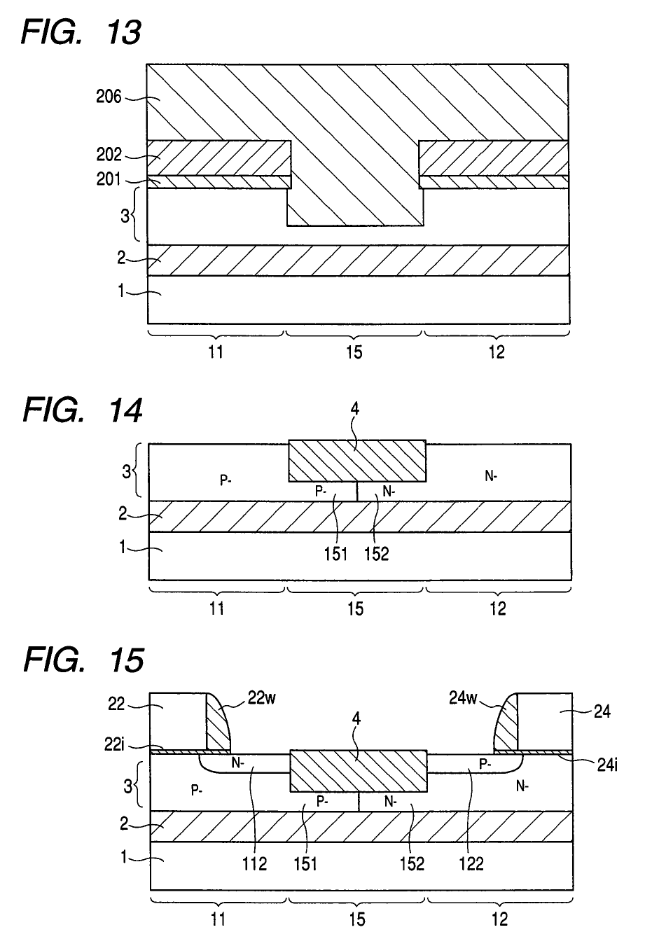

Subsequently, the resist 205 is removed, and a silicon oxide film 206 is deposited to fill in the trench (FIG. 13). Then, by CMP, the silicon oxide film 206 on the silicon nitride film 202 is removed. Then, the silicon nitride film 202 is removed. As a result, the active regions 11 to 14 are defined. At this step, as shown in FIG. 13, under the trench between the first active region 11 and the second active region 12, the SOI layer 3 to serve as the wiring structure 15 remains (although not shown, between the third active region 13 and the fourth active region 14, the SOI layer 3 to serve as the wiring structure 16 also remains).

To respective active regions 11 to 14, ion implantation (channel dope) for forming the channel region of transistors is performed. To the active regions 11 and 13 of the NMOS region, for example, boron (B) is implanted at an implantation energy of several tens of keV, and at a dose amount of several e13/cm². Further, boron is implanted at an implantation energy of several keV, and at a dose amount of several e12/cm². On the other hand, to the active regions 12 and 14 of the PMOS region, for example, phosphorus (P) is implanted at several hundreds of keV, and at several e13/cm². Further, arsenic (As) is implanted at several tens of keV and at several e12/cm². As a result, the active regions 11 and 13 become P⁻ type. The second active regions 12 and 14 become N⁻ type. Further, in accordance with the channel doping step, in the wiring structures 15 and 16 which are the SOI layer under the trench, the P⁻ region and the N⁻ region are formed (FIG. 14). In FIG. 14, the P⁻ region 151 and the N⁻ region 152 in the wiring structure 15 are shown. Then, the silicon oxide film 201 is removed, so that an isolation oxide film 4 is formed in the trench.

Subsequently, on the top surfaces of the active regions 11 to 14, an oxide film is formed. A polysilicon film is formed entirely thereon. These are patterned to form gate electrodes 22 to 24 having a gate insulation film on the underside. Then, to the active regions 11 and 13 of the NMOS region, for example, arsenic (As) is implanted at an implantation energy of several keV, and at a dose amount of several e14/cm². As a result, the LDD regions of the access transistors Q1 and Q4 and the LDD regions of the driver transistors Q2 and Q5 are formed. On the other hand, to the active regions 12 and 14 of the PMOS region, for example, boron is implanted at several keV and at several e14/cm². As a result, the LDD regions of the load transistors Q3 and Q6 are formed. In FIG. 15, the LDD region 112 of the driver transistor Q2 and the LDD region 122 of the load transistor Q3 are shown. Thereafter, a silicon oxide film is deposited over the entire surface, and etched back. As a result, on the side surfaces of the gate electrodes 21 to 24, a sidewall is formed (FIG. 15). In FIG. 15, there are shown the gate electrode 22, and a gate insulation film 22i and a sidewall 22w thereof, and the gate electrode 24, and a gate insulation film 24i and a sidewall 24w thereof.

Then, to the active regions 11 and 13 in the NMOS region, for example, arsenic (As) is implanted at an implantation energy of several tens of keV and at a dose amount of several e15/cm². Further, phosphorus (P) is implanted at several tens of keV and at several e14/cm². As a result, the source/drain regions of the access transistors Q1 and Q4 and the driver transistors Q2 and Q5 are formed. On the other hand, to the active regions 12 and 14 of the PMOS region, for example, boron is implanted at several keV and several e15/cm². As a result, the source/drain regions of the load transistors Q3 and Q6 are formed.

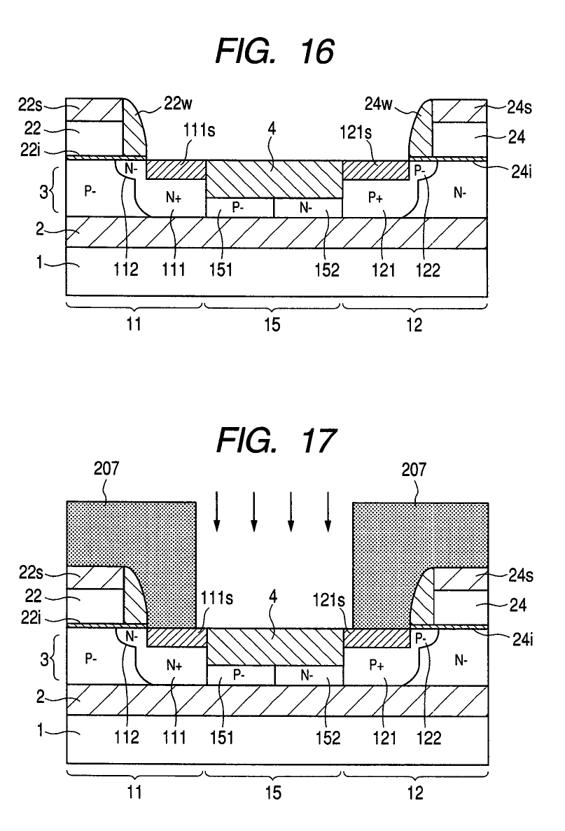

Then, on the entire surface, for example, a metal film of Co, Ni, Pt, Ti, or the like is formed. Then, lamp annealing at about 600° C. is carried out. As a result, on the top surfaces of the active regions 11 to 14 and the gate electrodes 21 to 24, a silicide layer is formed in a self-alignment manner (FIG. 16). In FIG. 16, there are shown the drain region 111 of the driver transistor Q2 (which is also the source/drain region of the access transistor Q1) and a silicide layer ills, the drain region 121 of the load transistor Q3, and a silicide layer 121s thereof, a silicide layer 22s of the gate electrode 22, and a silicide layer 24s of the gate electrode 24.

The steps up to this point are roughly the same as the manufacturing steps of a conventional SRAM cell, except that for forming the partial trench isolation, the wiring structures 15 and 16 are formed.

In this embodiment, hereinafter, a resist 207 opened above the wiring structures 15 and 16 is formed. By the use of it as a mask, to the wiring structures 15 and 16, Si, N, F, Ge, As, P, BF₂, B, In, Ar, or the like is implanted, thereby to cause a crystal defect (FIG. 17). As a result, a leak current is caused at the PN junction of the wiring structures 15 and 16.

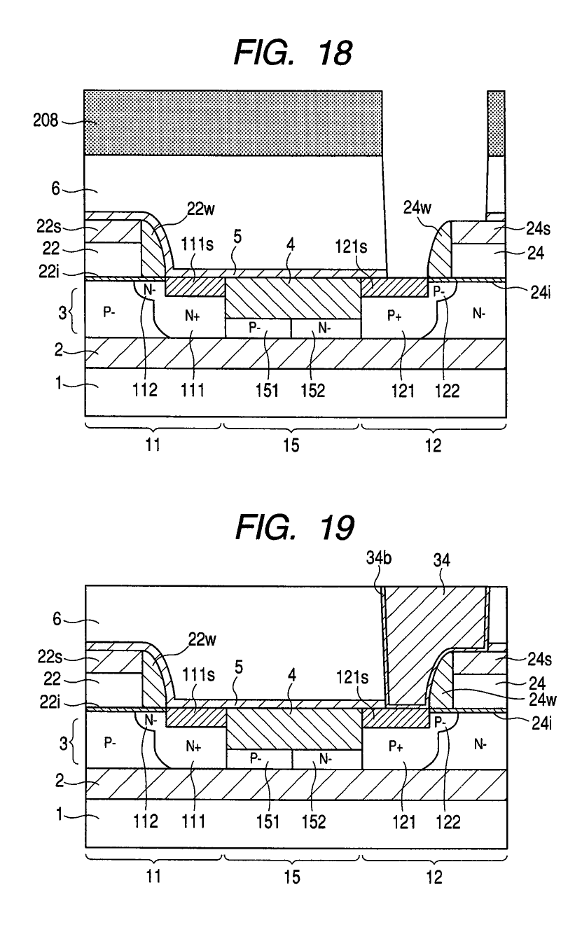

Then, on the entire surface, a silicon nitride film 5 is deposited to several tens of nanometers. Then, a silicon oxide film is deposited to about several hundreds of nanometers, thereby to form an interlayer insulation film 6. Then, the top surface of the interlayer insulation film 6 is subjected to planarization by CMP. Thereafter, a resist 208 opened at the formation region of a contact is formed. With etching using it as a mask, a contact hole is formed in the silicon nitride film 5 and the interlayer insulation film 6 (FIG. 18).

Then, the resist 208 is removed, and a barrier metal such as Ti and a wiring material such as W are deposited to fill in the contact hole. By removing the excess barrier metal and wiring material on the interlayer insulation film 6, a contact plug is formed. Further, wiring is carried out. In FIG. 19, there are shown a shared contact 34 coupled to both the gate electrode 24 and the drain region 121 of the load transistor Q3, and a barrier metal 34b on the surface.

By the steps up to this point, the SRAM cell in accordance with this embodiment shown in FIGS. 5 and 6 is formed.

### Embodiment 2

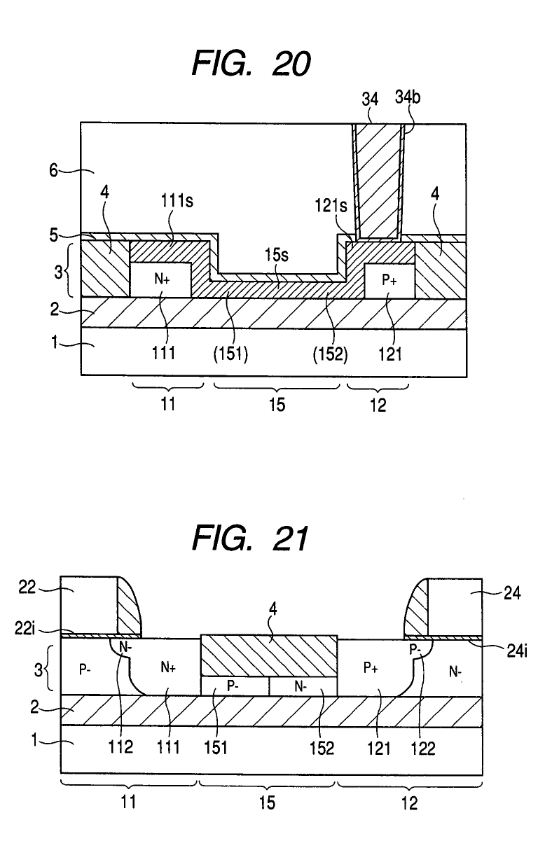

FIG. 20 is a view for illustrating a configuration of a SRAM cell in accordance with Embodiment 2, and a view showing a mutual coupling structure of an access transistor Q1, a driver transistor Q2, and a load transistor Q3 in the SRAM cell. The top view of the SRAM cell in accordance with Embodiment 2 is the same as FIG. 5 shown in Embodiment 1. FIG. 20 corresponds to a cross sectional view along line A-A thereof.

Incidentally, also in this embodiment, the access transistor Q4, the driver transistor Q5, and the load transistor Q6 are similar in configuration to the access transistor Q1, the driver transistor Q2, and the load transistor Q3, respectively. Therefore, herein, a description will be typically given to the coupling structure among the access transistor Q1, the driver transistor Q2, and the load transistor Q3.

As shown in FIG. 20, in this embodiment, in the wiring structure 15 which couples the drain region 111 of the driver transistor Q2 and the drain region 121 of the load transistor Q3, a silicide layer 15s integral with a silicide layer ills in the upper part of the drain region 111 and a silicide layer 121s in the upper part of the drain region 121 is formed. Namely, the silicide layer 15s formed in the wiring structure 15 is coupled to the drain region 111 at one end, and coupled to the drain region 121 at the other end. Therefore, an electrical coupling between the drain region 111 of the driver transistor Q2 and the drain region 121 of the load transistor Q3 is established by the silicide layer 15s formed in the wiring structure 15.

Incidentally, in FIG. 20, there is shown an example in which the wiring structure 15 has been entirely silicidated. However, it is essential only that the silicide layer 15s is formed at least in the upper part of the wiring structure 15. Further, as the silicide layer 15s, mention may be made of CoSi₂, NiSi, PtSi, TiSi₂, or the like. Whereas, although a description is omitted, the wiring structure 16 coupling the drain region of the driver transistor Q5 and the drain region of the load transistor Q6 is also similar in configuration to the wiring structure 15.

Also in this embodiment, the drain region 111 of the driver transistor Q2 and the drain region 121 of the load transistor Q3 are coupled to each other via the wiring structure 15 under trench isolation. The first active region 11 and the second active region 12 are not coupled to each other via the upper part of the SOI layer 3. Accordingly, as with FIG. 7 shown in Embodiment 1, there will not occur widening of the width of the first active region 11 by the roundness of the corner portions generated upon forming the active regions. The same also applies to the active regions 12 to 14.

Therefore, also in this embodiment, even when misalignment of the gate electrodes 21 to 24 occurs in the direction of gate length thereof, each gate width of respective transistors Q1 to Q6 shows almost no changes. This can suppress the variation in electrical characteristics thereof. Still further, as with the SRAM cell shown in FIGS. 2 and 3, the cell area and the bit line capacitance can be reduced.

Below, a description will be given to the manufacturing process of the SRAM cell in accordance with Embodiment 2. FIGS. 21 to 24 are views showing the manufacturing process of the SRAM cell in accordance with this embodiment. These respective views each correspond to the cross section along line C-C of FIG. 5.

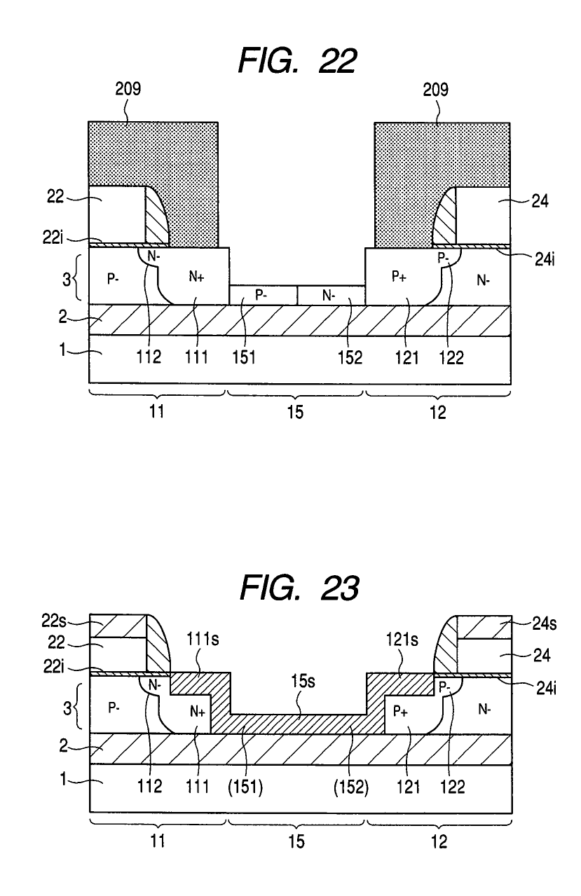

First, by the same steps as those described by reference to FIGS. 8 to 15 in Embodiment 1, on a SOI board, an isolation oxide film 4, wiring structures 15 and 16, gate electrodes 21 to 14, and LDD regions and source/drain regions of the transistors Q1 to Q6 are successively formed (FIG. 21). In this embodiment, hereinafter, prior to the formation of the silicide layer, a resist 209 opened above the wiring structures 15 and 16 is formed. By etching using it as a mask, the isolation oxide film 4 on the wiring structures 15 and 16 is removed (FIG. 22). Thereafter, the resist 209 is removed.

Then, on the entire surface, for example, a metal film of Co, Ni, Pt, Ti, or the like is formed. Then, lamp annealing at about 600° C. is carried out. As a result, on the active regions 11 to 14, the gate electrodes 21 to 24, and the wiring structures 15 and 16, a silicide layer is formed in a self-alignment manner (FIG. 23). In FIG. 23, there are shown a silicide layer 111s of the drain region 111 of the driver transistor Q2, a silicide layer 121s of the drain region 121 of the load transistor Q3, a silicide layer 22s of the gate electrode 22, and a silicide layer 24s of the gate electrode 24, and a silicide layer 15s on the wiring structure 15. As in FIG. 23, the silicide layer 15s on the wiring structure 15 is integrally formed with the silicide layer 111s of the drain region 111, and the silicide layer 121s of the drain region 121.

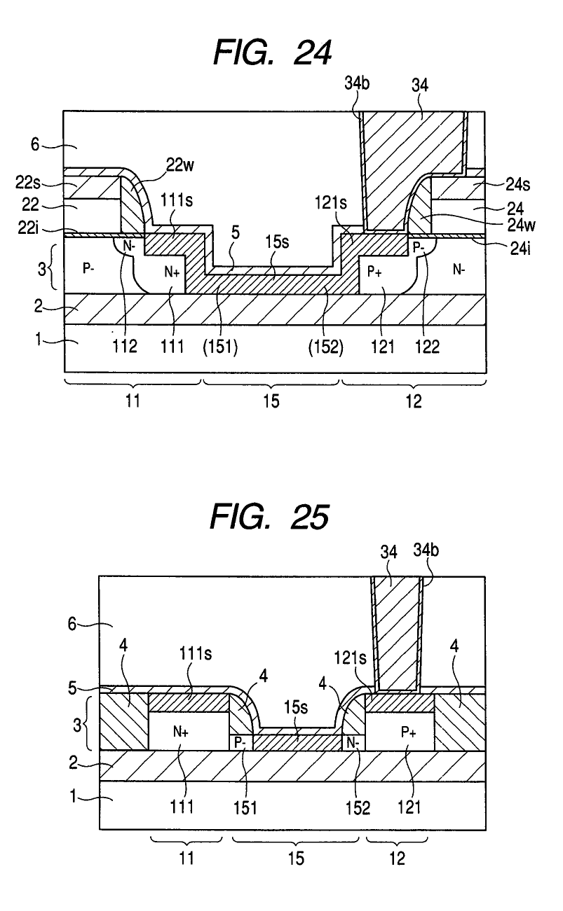

Thereafter, by the same steps as those described by reference to FIGS. 18 and 19 in Embodiment 1, a silicon nitride film 5 and an interlayer insulation film 6 are formed on the entire surface. Then, a contact plug is formed therein. In FIG. 24, there are shown a shared contact 34 coupled to both the gate electrode 24 and the drain region 121 of the load transistor Q3, and a barrier metal 34b on the surface. By the steps up to this point, the SRAM cell in accordance with Embodiment 2 is formed.

### Embodiment 3

FIG. 25 is a view for illustrating a configuration of a SRAM cell in accordance with Embodiment 3, and a view showing a mutual coupling structure of an access transistor Q1, a driver transistor Q2, and a load transistor Q3 in the SRAM cell. The top view of the SRAM cell in accordance with Embodiment 3 is the same as FIG. 5 shown in Embodiment 1. FIG. 25 corresponds to a cross sectional view along line A-A thereof.

Incidentally, also in this embodiment, the access transistor Q4, the driver transistor Q5, and the load transistor Q6 are similar in configuration to the access transistor Q1, the driver transistor Q2, and the load transistor Q3, respectively. Therefore, herein, a description will be typically given to the coupling structure among the access transistor Q1, the driver transistor Q2, and the load transistor Q3.

As shown in FIG. 25, in this embodiment, in the wiring structure 15 which couples the drain region 111 of the driver transistor Q2 and the drain region 121 of the load transistor Q3, a silicide layer 15s is formed. However, as distinct from Embodiment 2, the silicide layer 15s is formed only at the intermediate portion between the drain region 111 and the drain region 121. The opposite sides thereof are not coupled to the drain region 111 and the drain region 121. Namely, a P⁻ region 151 is interposed between the silicide layer 15s and the drain region 111. Whereas, an N⁻ region 152 is interposed between the silicide layer 15s and the drain region 121.

In the wiring structure 15, the silicide layer 15s is formed across the P⁻ region 151 and the N⁻ region 152. Therefore, an electrical coupling between the P⁻ region 151 and the N⁻ region 152 is established via the silicide layer 15s. On the other hand, the P region 151 is interposed between the silicide layer 15s and the drain region 111 (N⁺ region). Whereas, the N⁻ region 152 is interposed between the silicide layer 15s and the drain region 121 (P⁺ region). Therefore, the wiring structure 15 has PN junctions at the opposite edges.

However, the distance between the silicide layer 15s and the drain region 111 (the width of the P⁻ region 151), and the distance between the silicide layer 15s and the drain region 121 (the width of the N⁻ region 152) are short. Therefore, during the operation of the SRAM cell, the P⁻ region 151 and the N⁻ region 152 are depleted. As a result, a leak current due to a punch through phenomenon flows. In this embodiment, the electrical coupling between the drain region 111 and the drain region 121 is established by the leak current. The magnitude of the leak current can be set at about 10⁻⁹ A to 1 A. Alternatively, as with Embodiment 1, by forming a crystal defect in the wiring structure 15 with ion implantation, a leak current may be caused at the PN junction.

Incidentally, in FIG. 25, there is shown an example in which the whole of the central part (from the top surface to the bottom surface) of the wiring structure 15 has been silicidated. However, it is essential only that the silicide layer 15s is formed at least in the upper part of the center of the wiring structure 15. Whereas, although a description is omitted, the wiring structure 16 coupling the drain region of the driver transistor Q5 and the drain region of the load transistor Q6 is also similar in configuration to the wiring structure 15.

Also in this embodiment, the drain region 111 of the driver transistor Q2 and the drain region 121 of the load transistor Q3 are coupled to each other via the wiring structure 15 under trench isolation. The first active region 11 and the second active region 12 are not coupled to each other via the upper part of the SOI layer 3. Accordingly, as with FIG. 7 shown in Embodiment 1, there will not occur widening of the width of the first active region 11 by the roundness of the corner portions generated upon forming the active regions. The same also applies to the active regions 12 to 14.

Therefore, also in this embodiment, even when misalignment of the gate electrodes 21 to 24 occurs in the direction of gate length thereof, each gate width of respective transistors Q1 to Q6 shows almost no changes. This can suppress the variation in electrical characteristics thereof. Still further, as with the SRAM cell shown in FIGS. 2 and 3, the cell area and the bit line capacitance can be reduced. Further, the coupling between the driver transistor Q2 and the load transistor Q3, and the coupling between the driver transistor Q5 and the load transistor Q6 are established relatively high resistance wiring structures 15 and 16, respectively. As a result, each functions as a feedback resistance, which also produces an effect of reducing a soft error.

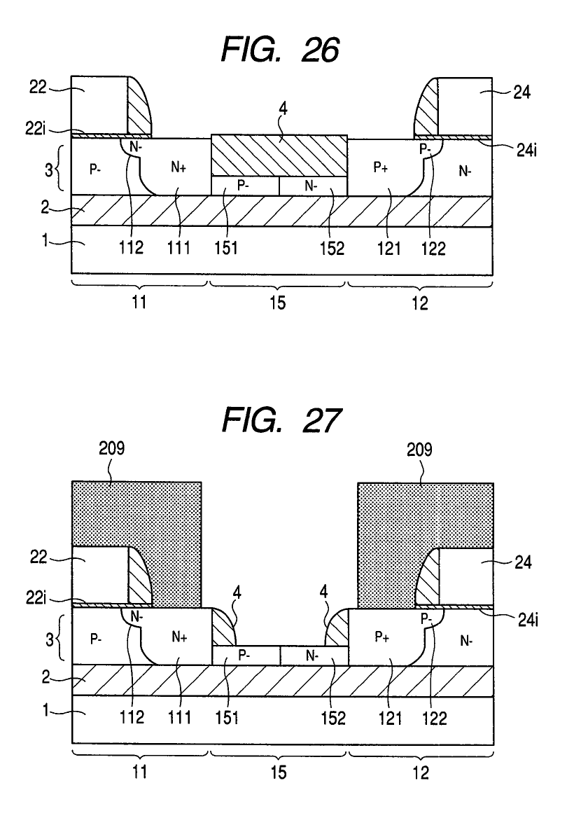

Below, a description will be given to the manufacturing process of the SRAM cell in accordance with Embodiment 3. FIGS. 26 to 29 are views showing the manufacturing process of the SRAM cell in accordance with this embodiment. These respective views each correspond to the cross section along line C-C of FIG. 5.

First, by the same steps as those described by reference to FIGS. 8 to 15 in Embodiment 1, on a SOI board, an isolation oxide film 4, wiring structures 15 and 16, gate electrodes 21 to 24, the LDD regions of the transistors Q1 to Q6, and source/drain regions thereof are successively formed.

Then, as with Embodiment 2, prior to the formation of the silicide layer, a resist 209 opened above the wiring structures 15 and 16 is formed. By etching using it as a mask, the isolation oxide film 4 on the wiring structures 15 and 16 is removed (FIG. 27). In this embodiment, at this step, the isolation oxide film 4 in the opening of the resist 9 is not fully removed. As in FIG. 27, a part of the isolation oxide film 4 is left on the sidewalls of the active regions 11 to 14. Alternatively, at this step, ion implantation using the resist 209 as a mask may be carried out to cause a crystal defect in the wiring structures 15 and 16. Thereafter, the resist 209 is removed.

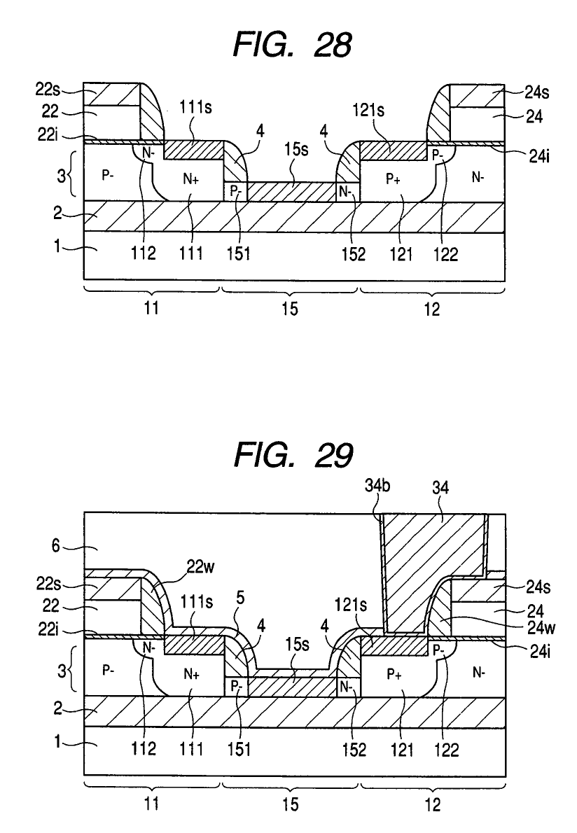

Then, on the entire surface, for example, a metal film of Co, Ni, Pt, Ti, or the like is formed. Then, lamp annealing at about 600° C. is carried out. As a result, on the active regions 11 to 14, the gate electrodes 21 to 24, and the central parts of the wiring structures 15 and 16, a silicide layer is formed in a self-alignment manner (FIG. 28). In FIG. 28, there are shown a silicide layer ills of the drain region 111 of the driver transistor Q2, a silicide layer 121s of the drain region 121 of the load transistor Q3, a silicide layer 22s of the gate electrode 22, and a silicide layer 24s of the gate electrode 24, and a silicide layer 15s on the wiring structure 15.

Thereafter, by the same steps as those described by reference to FIGS. 18 and 19 in Embodiment 1, on the entire surface, a silicon nitride film 5 and an interlayer insulation film 6 are formed. A contact plug is formed therein. In FIG. 29, there are shown a shared contact 34 coupled to both the gate electrode 24 and the drain region 121 of the load transistor Q3, and a barrier metal 34b on the surface. By the steps up to this point, the SRAM cell in accordance with Embodiment 3 is formed.

### Embodiment 4

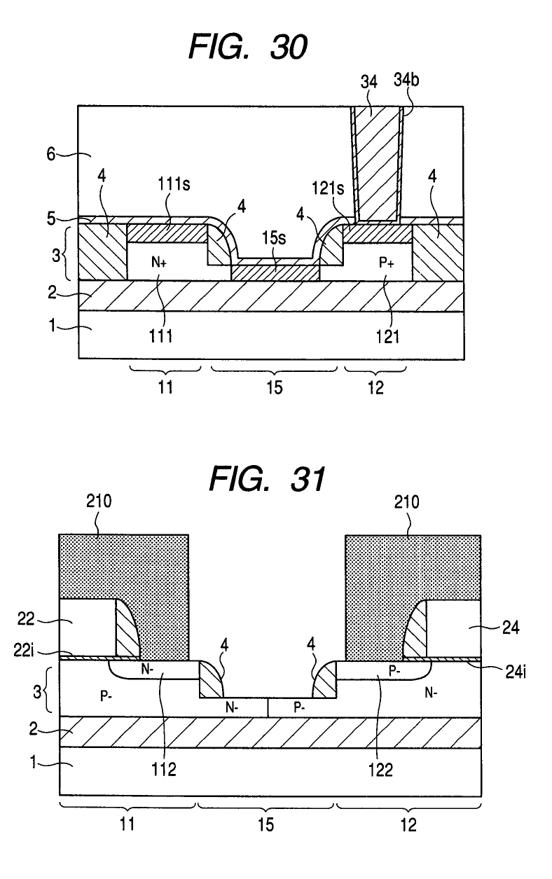

FIG. 30 is a view for illustrating a configuration of a SRAM cell in accordance with Embodiment 4, and a view showing a mutual coupling structure of an access transistor Q1, a driver transistor Q2, and a load transistor Q3 in the SRAM cell. The top view of the SRAM cell in accordance with Embodiment 4 is the same as FIG. 5 shown in Embodiment 1. FIG. 30 corresponds to a cross sectional view along line A-A thereof.

Incidentally, also in this embodiment, the access transistor Q4, the driver transistor Q5, and the load transistor Q6 are similar in configuration to the access transistor Q1, the driver transistor Q2, and the load transistor Q3, respectively. Therefore, herein, a description will be typically given to the coupling structure among the access transistor Q1, the driver transistor Q2, and the load transistor Q3.

As shown in FIG. 30, in this embodiment, in the wiring structure 15 which couples the drain region 111 of the driver transistor Q2 and the drain region 121 of the load transistor Q3, a silicide layer 15s is formed. Further, as with Embodiment 3, the silicide layer 15s is formed only at the intermediate portion between the drain region 111 and the drain region 121. However, in this embodiment, the drain region 111 (N⁺ region) and the drain region 121 (P⁺ region) extend even in the wiring structure 15. The silicide layer 15s is formed in such a manner as to be in contact with both of them. Namely, as with Embodiment 2, the silicide layer 15s is coupled to the drain region 111 at one end, and coupled to the drain region 121 at the other end. Thus, an electrical coupling therebetween is established by the silicide layer 15s formed in the wiring structure 15.

Incidentally, in FIG. 30, there is shown an example in which the whole of the central part (from the top surface to the bottom surface) of the wiring structure 15 has been silicidated. However, it is essential only that the silicide layer 15s is formed at least in the upper part of the center of the wiring structure 15. Whereas, although a description is omitted, the wiring structure 16 coupling the drain region of the driver transistor Q5 and the drain region of the load transistor Q6 is also similar in configuration to the wiring structure 15.

Also in this embodiment, the drain region 111 of the driver transistor Q2 and the drain region 121 of the load transistor Q3 are coupled to each other via the wiring structure 15 under trench isolation. The first active region 11 and the second active region 12 are not coupled to each other via the upper part of the SOI layer 3. Accordingly, as with FIG. 7 shown in Embodiment 1, there will not occur widening of the width of the first active region 11 by the roundness of the corner portions generated upon forming the active regions. The same also applies to the active regions 12 to 14.

Therefore, also in this embodiment, even when misalignment of the gate electrodes 21 to 24 occurs in the direction of gate length thereof, each gate width of respective transistors Q1 to Q6 shows almost no changes. This can suppress the variation in electrical characteristics thereof. Still further, as with the SRAM cell shown in FIGS. 2 and 3, the cell area and the bit line capacitance can be reduced. Further, in this embodiment, for example, as distinct from Embodiment 2, the silicide layer 15s of the wiring structure 15 is not directly coupled with the silicide layer 111s of the drain region 111 and the silicide layer 121s of the drain region 121. Therefore, the coupling resistance between the drain region 111 of the driver transistor Q2 and the drain region 121 of the load transistor Q3 becomes a relatively high resistance. As a result, the coupling resistance functions as a feedback resistance, which also produces an effect of reducing a soft error.

Below, a description will be given to the manufacturing process of the SRAM cell in accordance with Embodiment 4. FIGS. 31 to 34 are views showing the manufacturing process of the SRAM cell in accordance with this embodiment. These respective views each correspond to the cross section along line C-C of FIG. 5.

First, by the same steps as those described by reference to FIGS. 8 to 15 in Embodiment 1, on a SOI board, an isolation oxide film 4, wiring structures 15 and 16, gate electrodes 21 to 24, and the LDD regions of the transistors Q1 to Q6 are successively formed.

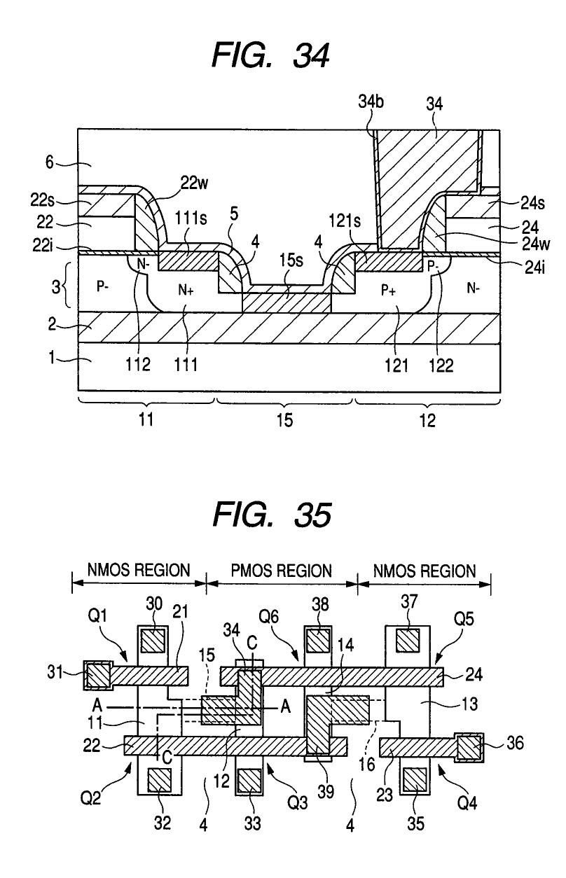

In this embodiment, prior to the formation of the source/drain regions of the transistors Q1 to Q6, a resist 210 opened above the wiring structures 15 and 16 is formed. By etching using it as a mask, the isolation oxide film 4 on the wiring structures 15 and 16 is removed (FIG. 31). In this embodiment, as in FIG. 34, a part of the isolation oxide film 4 is left on the sidewalls of the active regions 11 to 14. However, the isolation oxide film 4 in the opening of the resist 110 may be fully removed. Thereafter, the resist 209 is removed.

Then, to the active regions 11 and 13 in the NMOS region, for example, arsenic (As) is implanted at an implantation energy of several tens of keV, and at a dose amount of several e15/cm². Further, phosphorus (P) is implanted at several tens of keV, and at several e14/cm². As a result, the source/drain regions of the access transistors Q1 and Q4 and the driver transistors Q2 and Q5 are formed. On the other hand, to the active regions 12 and 14 of the PMOS region, for example, boron is implanted at several keV and at several e15/cm². As a result, the source/drain regions of the load transistors Q3 and Q6 are formed.

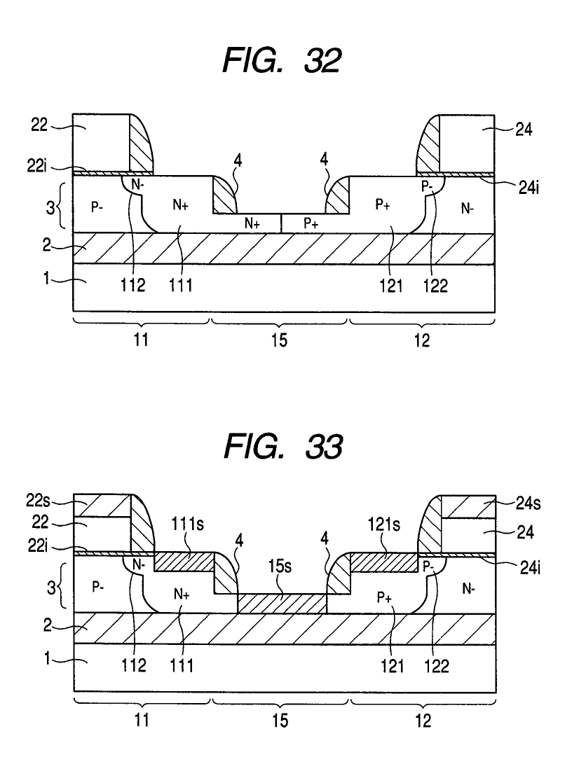

At this step, the isolation oxide film 4 on the wiring structure 15 has been removed. Accordingly, the implanted ions are introduced even into the wiring structures 15 and 16. As a result, as shown in FIG. 32, the drain region 111 of the driver transistor Q2 and the drain region 121 of the load transistor Q3 are formed in such a manner as to extend even in the central part in the wiring structure 15. Whereas, although not shown, the drain region of the driver transistor Q5 and the drain region of the load transistor Q6 are also formed in such a manner as to extend even in the central part in the wiring structure 16.

Then, on the entire surface, for example, a metal film of Co, Ni, Pt, Ti, or the like is formed. Then, lamp annealing at about 600° C. is carried out. As a result, on the active regions 11 to 14, the gate electrodes 21 to 24, and the central parts of the wiring structures 15 and 16, a silicide layer is formed in a self-alignment manner (FIG. 33). In FIG. 33, there are shown a silicide layer 111s of the drain region 111 of the driver transistor Q2, a silicide layer 121s of the drain region 121 of the load transistor Q3, a silicide layer 22s of the gate electrode 22, and a silicide layer 24s of the gate electrode 24, and a silicide layer 15s on the wiring structure 15.

Thereafter, by the same steps as those described by reference to FIGS. 18 and 19 in Embodiment 1, on the entire surface, a silicon nitride film 5 and an interlayer insulation film 6 are formed. A contact plug is formed therein. In FIG. 34, there are shown a shared contact 34 coupled to both the gate electrode 24 and the drain region 121 of the load transistor Q3, and a barrier metal 34b on the surface. By the steps up to this point, the SRAM cell in accordance with Embodiment 4 is formed.

### Embodiment 5

FIG. 35 is a top view showing the layout of a SRAM cell in accordance with Embodiment 5. In the same view, the elements having the same functions as those in FIG. 5 shown in Embodiment 1 are given the same reference numerals and signs.

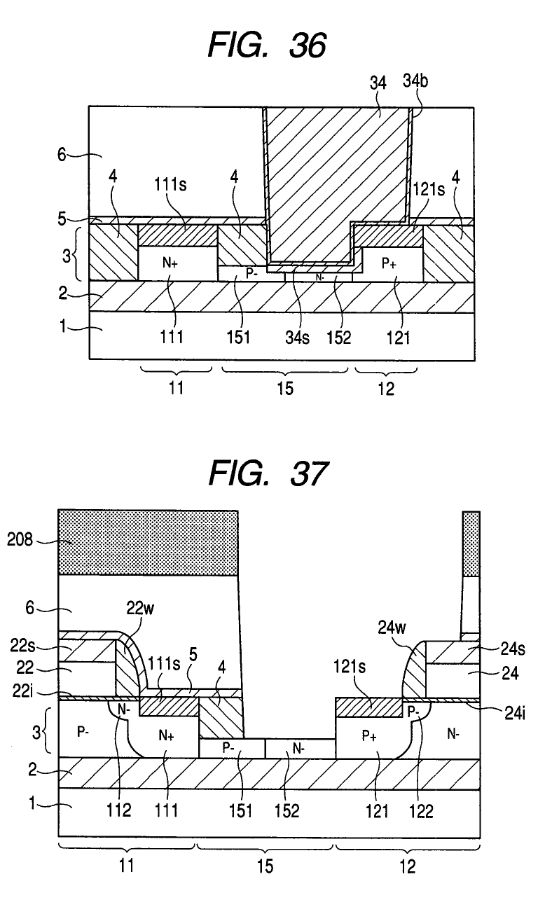

In the SRAM cell of Embodiment 5, as in FIG. 35, a shared contact 34 is formed across not only the gate electrode 24 and the drain region of the load transistor Q3, but also the wiring structure 15. Similarly, a shared contact 39 is formed across not only the gate electrode 22 and the drain region of the load transistor Q6, but also the wiring structure 16.

Whereas, FIG. 36 is a view for illustrating a configuration of the SRAM cell in accordance with Embodiment 5, and a view showing a mutual coupling structure among an access transistor Q1, a driver transistor Q2, and a load transistor Q3 in the SRAM cell. It corresponds to a cross sectional view along line A-A of FIG. 35.

Incidentally, also in this embodiment, the access transistor Q4, the driver transistor Q5, and the load transistor Q6 are similar in configuration to the access transistor Q1, the driver transistor Q2, and the load transistor Q3, respectively. Therefore, herein, a description will be typically given to the coupling structure among the access transistor Q1, the driver transistor Q2, and the load transistor Q3.

As shown in FIGS. 35 and 36, the shared contact 34 is coupled to the gate electrode 24 of the driver transistor Q5 and the load transistor Q6, the drain region 121 of the load transistor Q3, and the wiring structure 15. Further, as in FIG. 36, at the boundary of the shared contact 34 and the wiring structure 15 and the drain region 121, a silicide layer 34s resulting from the reaction between the barrier metal 34b on the surface of the shared contact 34 and the SOI layer 3 is formed. Further, the shared contact 34 is coupled across the P⁻ region 151, the N⁻ region 152, and the drain region 121. Accordingly, these three regions are mutually electrically coupled. However, between the shared contact 34 and the drain region 111, there is interposed a PN junction at the boundary between the drain region 111 and the P⁻ region 151.

However, the distance between the shared contact 34 and the drain region 111 is short. Therefore, during the operation of the SRAM cell, the P⁻ region 151 is depleted. As a result, a leak current due to a punch through phenomenon flows. In this embodiment, the electrical coupling between the drain region 111 and the drain region 121 is established by the leak current. The magnitude of the leak current can be set at about 10⁻⁹ A to 1 A. Alternatively, as with Embodiment 1, by forming a crystal defect in the wiring structure 15 with ion implantation, a leak current may be caused at the PN junction.

Incidentally, in FIG. 36, there is shown an example in which the silicide layer 34s is formed only in the top portion of the wiring structure 15. However, the silicide layer 34s may extend from the top surface to the bottom surface of the wiring structure 15. Whereas, although a description is omitted, the wiring structure 16 coupling the drain region of the driver transistor Q5 and the drain region of the load transistor Q6 is also similar in configuration to the wiring structure 15.

In this embodiment, the drain region 111 of the driver transistor Q2 and the drain region 121 of the load transistor Q3 are coupled to each other via the wiring structure 15 under trench isolation and the shared contact. The first active region 11 and the second active region 12 are not coupled to each other via the upper part of the SOI layer 3. Accordingly, as with FIG. 7 shown in Embodiment 1, there will not occur widening of the width of the first active region 11 by the roundness of the corner portions generated upon forming the active regions. The same also applies to the active regions 12 to 14.

Therefore, also in this embodiment, even when misalignment of the gate electrodes 21 to 24 occurs in the direction of gate length thereof, each gate width of respective transistors Q1 to Q6 shows almost no changes. This can suppress the variation in electrical characteristics thereof. Still further, as with the SRAM cell shown in FIGS. 2 and 3, the cell area and the bit line capacitance can be reduced. Further, in this embodiment, a relatively high resistance P⁻ region 15 is interposed between the shared contact 34 and the drain region 111. Therefore, the coupling resistance functions as a feedback resistance, which also produces an effect of reducing a soft error.

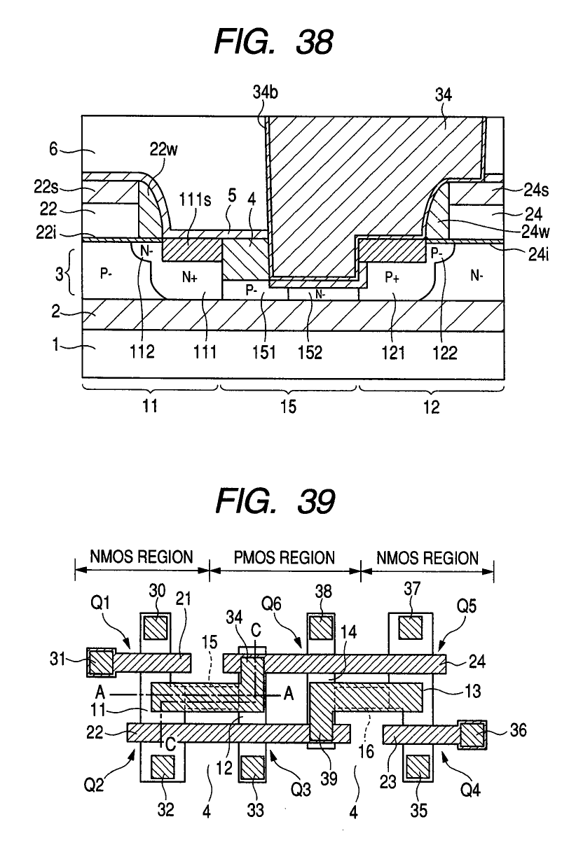

FIGS. 37 and 38 are views for illustrating a manufacturing method of the SRAM cell in accordance with this embodiment. These views show a process for forming the shared contact 34 in the steps of forming the contacts 30 to 39, and each correspond to a cross section along line C-C of FIG. 35.

The manufacturing process of the SRAM cell in accordance with Embodiment 5 is roughly the same as in Embodiment 1. Namely, only the following process is enough. In the steps of forming the contacts 30 to 39 (FIGS. 18 and 19) in the manufacturing process of the SRAM cell of Embodiment 1, the opening patterns of the shared contacts 34 and 39 in the resist 208 are changed so as to extend across the wiring structures 15 and 16, respectively, as in FIG. 35. However, the contact holes for the shared contacts 34 and 39 are required to be formed so as to reach the wiring structures 15 and 16, respectively, under the isolation oxide film 4 (FIG. 37). Then, in each contact hole, a contact plug having a barrier metal is formed (FIG. 38). Other steps are the same as those in Embodiment 1, and hence, a description thereon is omitted.

### Embodiment 6

Embodiment 6 is a modified example of Embodiment 5 described previously. FIG. 39 is a top view showing a layout of a SRAM cell in accordance with Embodiment 6. As shown in the same view, in this embodiment, the shared contact 34 is allowed to extend to the gate electrode 24, the drain region of the load transistor Q3, and the wiring structure 15, and in addition, to the drain region of the driver transistor Q2. Similarly, the shared contact 39 is allowed to extend to the gate electrode 22 and the drain region of the load transistor Q6, and in addition, to the drain region of the access transistor Q4.

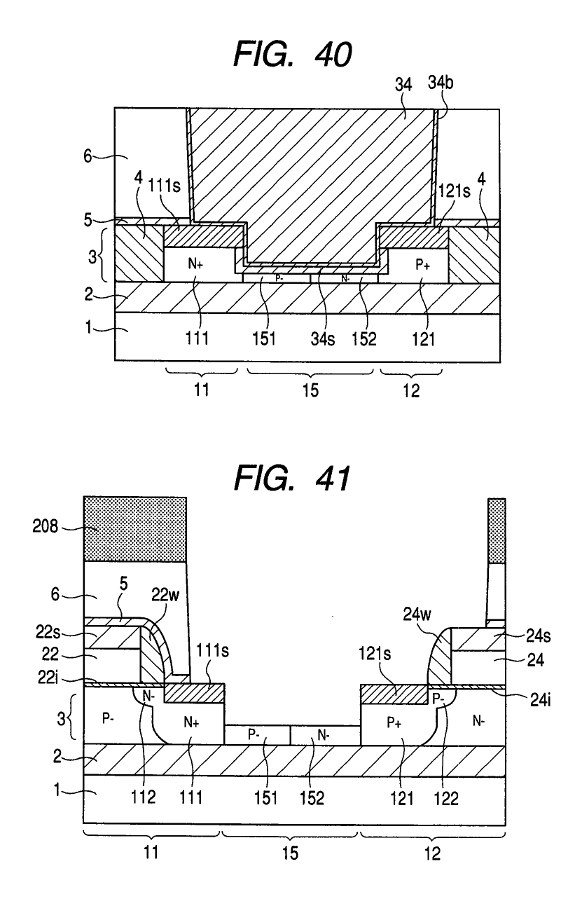

FIG. 40 is a view for illustrating a configuration of the SRAM cell in accordance with Embodiment 6. It corresponds to a cross sectional view along line A-A of FIG. 39. Also in this embodiment, the access transistor Q4, the driver transistor Q5, and the load transistor Q6 are similar in configuration to the access transistor Q1, the driver transistor Q2, and the load transistor Q3, respectively. Therefore, herein, a description will be typically given to the coupling structure among the access transistor Q1, the driver transistor Q2, and the load transistor Q3.

As shown in FIGS. 39 and 40, the shared contact 34 is coupled to the gate electrode 24 of the driver transistor Q5 and the load transistor Q6, the drain region 121 of the load transistor Q3, the wiring structure 15, and the drain region 111 of the driver transistor Q2. Further, as in FIG. 39, at the boundary of the shared contact 34 and the wiring structure 15, and the drain region 111 and the drain region 121, a silicide layer 34s resulting from the reaction between the barrier metal 34b on the surface of the shared contact 34 and the SOI layer 3 is formed. Whereas, the shared contact 34 is coupled to both of the drain region 111 and the drain region 121, and hence it functions as wiring for electrically coupling both of them.

Incidentally, in FIG. 40, there is shown an example in which the silicide layer 34s is formed only in the top portion of the wiring structure 15. However, the silicide layer 34s may be formed in the whole of the wiring structure 15. Whereas, although a description is omitted, the wiring structure 16 coupling the drain region of the driver transistor Q5 and the drain region of the load transistor Q6 is also similar in configuration to the wiring structure 15.

In this embodiment, the drain region 111 of the driver transistor Q2 and the drain region 121 of the load transistor Q3 are coupled to each other via the wiring structure 15 under trench isolation and the share contact 34. The first active region 11 and the second active region 12 are not coupled to each other via the upper part of the SOI layer 3. Accordingly, as with FIG. 7 shown in Embodiment 1, there will not occur widening of the width of the first active region 11 by the roundness of the corner portions generated upon forming the active regions. The same also applies to the active regions 12 to 14.

Therefore, also in this embodiment, even when misalignment of the gate electrodes 21 to 24 occurs in the direction of gate length thereof, each gate width of respective transistors Q1 to Q6 shows almost no changes. This can suppress the variation in electrical characteristics thereof. Still further, as with the SRAM cell shown in FIGS. 2 and 3, the cell area and the bit line capacitance can be reduced.

FIGS. 41 and 42 are views for illustrating a manufacturing method of the SRAM cell in accordance with this embodiment. These views shows a process for forming the shared contact 34 in the steps of forming the contacts 30 to 39, and each correspond to a cross section along line C-C of FIG. 39.

The manufacturing process of the SRAM cell in accordance with Embodiment 6 is also roughly the same as in Embodiment 1. Namely, only the following process is enough. In the steps of forming the contacts 30 to 39 (FIGS. 18 and 19) in the manufacturing process of the SRAM cell of Embodiment 1, the opening patterns of the shared contacts 34 and 39 in the resist 208 are changed to the patterns as shown in FIG. 39. However, the contact holes for the shared contacts 34 and 39 are required to be formed so as to reach the wiring structures 15 and 16, respectively, under the isolation oxide film 4 (FIG. 41). Then, in each contact hole, a contact plug having a barrier metal is formed (FIG. 42). Other steps are the same as those in Embodiment 1, and hence, a description thereon is omitted.

### Embodiment 7

In respective embodiments up to this point, the trench isolation (isolation oxide film 4) defining the active regions 11 to 14 is configured to be full trench isolation except for the regions in which the wiring structures 15 and 16 are formed. However, it may also be configured to be partial trench isolation.

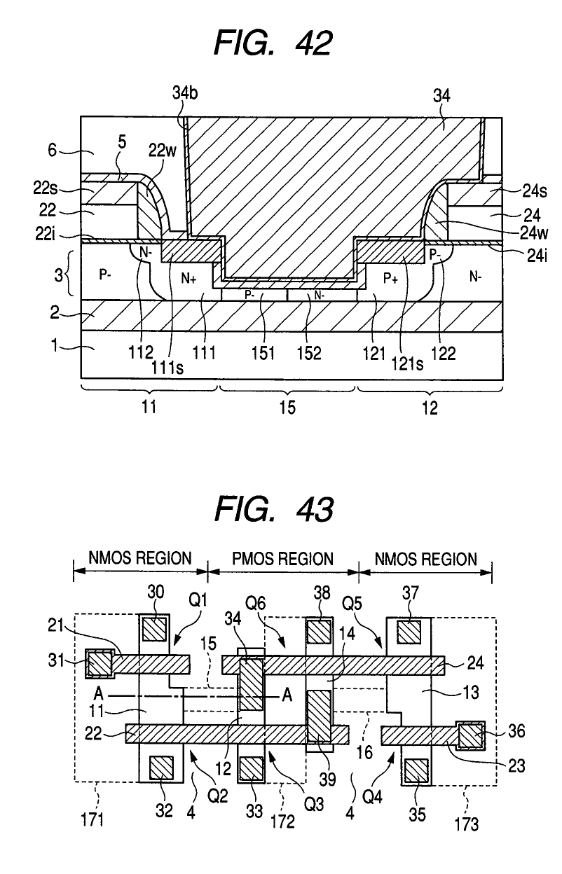

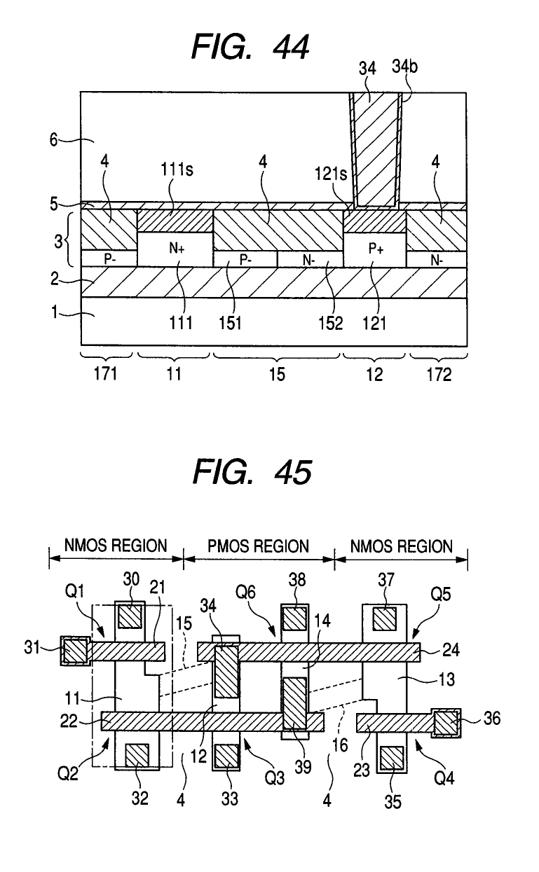

FIG. 43 is a top view showing a layout of a SRAM cell in accordance with Embodiment 7. FIG. 44 is a cross sectional view along line A-A thereof. The example of FIGS. 43 and 44 is configured as with the SRAM cell of Embodiment 1, except that not only the formation region of the wiring structures 15 and 16 but also the isolation oxide film 4 of the regions 171 to 173 shown in FIG. 43 are configured to be partial trench isolation. Namely, in the regions 171 to 173 (below, “PTI regions”) and the formation region of the wiring structures 15 and 16, as shown in FIG. 44, the isolation oxide film 4 is formed with a depth not reaching the BOX layer 2. The SOI layer 3 remains thereunder.

In FIGS. 43 and 44, the SOI layer 3 (P⁻ region) of the PTI region 171 adjacent to the first active region 11 is electrically coupled to the body (P⁻ region) of the access transistor Q1 and the driver transistor Q2. The SOI layer 3 (P⁻ region) of the PTI region 173 adjacent to the third active region 13 is electrically coupled to the body (P⁻ region) of the access transistor Q4 and the driver transistor Q5. The PTI region 172 (N⁻ region) between the second active region 12 and the fourth active region 14 is electrically coupled to the body (N⁻ region) of the load transistors Q3 and Q6.

Although not shown, in this embodiment, a plurality of SRAM cells are disposed in a matrix. The SOI layer 3 in the PTI regions 171 to 173 is shared between the adjacent cells. Whereas, the SOI layer 3 in the PTI regions 171 to 173 is respectively coupled to the body potential control terminals formed in a different region from the SRAM cell, and fixed at a given electrical potential through the control terminals.

Namely, in the SRAM cell in accordance with this embodiment, it is configured such that for the body potentials of respective transistors Q1 to Q6, a given potential is applied through the SOI layer 3 in the PTI regions 171 to 173 (SOI layer 3 under the isolation oxide film 4). Accordingly, the operations of respective transistors Q1 to Q6 are stabilized. This can contribute to the improvement of the operation reliability and an increase in speed of the operation.

Incidentally, in FIGS. 43 and 44, there is shown an example in which the PTI regions 171 to 173 are disposed in the SRAM cell of Embodiment 1. However, this embodiment is applicable to any of Embodiments 1 to 6 described above.

### Embodiment 8

In the embodiments up to this point, as in FIGS. 5, 35, and 39, the wiring structures 15 and 16 are laid out so as to extend at right angles with respect to the active regions 11 to 14. As described above, the wiring structures 15 and 16 are formed by using the SOI layer 3 under the partial trench isolation. Thus, they do not bring about changes in width of the active regions 11 to 14. Therefore, if required, the layout may be appropriately changed. For example, as in FIG. 45, it may be configured such that the wiring structures 15 and 16 extend in a direction oblique with respect to the active regions 11 to 14.

1. A semiconductor memory device, comprising a SRAM (Static Random Access Memory) cell including: a SOI (Silicon On Insulator) board including a support board, an insulation film, and a semiconductor layer stacked in this order; first and second active regions defined by trench isolation in the semiconductor layer; an access transistor and a driver transistor which are MOS (Metal-Oxide Semiconductor) transistors formed in the first active region; and a load transistor which is a MOS transistor formed in the second active region,
wherein the electrical coupling between a drain region of the driver transistor and a drain region of the load transistor is established by a wiring structure formed by using the semiconductor layer present under the trench isolation.

2. The semiconductor memory device according to claim 1,
wherein the wiring structure has at least one PN junction formed between the drain region of the driver transistor and the drain region of the load transistor, and
wherein in the wiring structure, a crystal defect causing a leak current in the PN junction is formed.

3. The semiconductor memory device according to claim 1,
wherein the wiring structure has at least one PN junction formed between the drain region of the driver transistor and the drain region of the load transistor, and
wherein in the wiring structure, a metal atom causing a leak current in the PN junction is introduced.

4. The semiconductor memory device according to claim 1,
wherein the wiring structure has a silicide layer coupled to the drain region of the driver transistor at one end, and coupled to the drain region of the load transistor at the other end.

5. The semiconductor memory device according to claim 1,
wherein the wiring structure has a silicide layer formed in the intermediate part between the drain region of the driver transistor and the drain region of the load transistor, and PN junctions formed over the opposite edges.

6. The semiconductor memory device according to claim 5,
wherein the electrical coupling between the drain region of the driver transistor and the drain region of the load transistor is established by a leak current of the PN junction due to a punch through phenomenon.

7. The semiconductor memory device according to claim 5,
wherein in the wiring structure, a crystal defect causing a leak current in the PN junction is formed.

8. The semiconductor memory device according to claim 1,
wherein the drain region of the driver transistor and the drain region of the load transistor extend to the inside of the wiring structure, and
wherein the wiring structure has a silicide layer in contact with both of the drain region of the driver transistor and the drain region of the load transistor.

9. The semiconductor memory device according to claim 1,
further comprising a contact plug coupled to the top surface of the wiring structure.

10. The semiconductor memory device according to claim 9,
wherein the wiring structure has at least one PN junction formed between the drain region of the driver transistor and the drain region of the load transistor, and
wherein the electrical coupling between the drain region of the driver transistor and the drain region of the load transistor is established by a leak current of the PN junction due to a punch through phenomenon.

11. The semiconductor memory device according to claim 9,
wherein the wiring structure has at least one PN junction formed between the drain region of the driver transistor and the drain region of the load transistor, and
wherein in the wiring structure, a crystal defect causing a leak current in the PN junction is formed.

12. The semiconductor memory device according to claim 9,
wherein the contact plug is coupled across the wiring structure and the drain region of the load transistor.

13. The semiconductor memory device according to claim 9,
wherein the contact plug is coupled across the wiring structure, the drain region of the driver transistor, and the drain region of the load transistor.

14. The semiconductor memory device according to claim 1,
wherein respective bodies of the access transistor, the driver transistor, and the load transistor are respectively applied with a given electrical potential via the semiconductor layer present under the trench isolation.
